(19) United States
(12) Patent Application Publication
(10) Pub. No.: US 2003/0058970 A1
(43) Pub. Date: Mar. 27, 2003

(54) Method and apparatus for measuring a waveform

(76) Inventors: John David Hamre, Plymouth, MN (US); Jan Brian Wilstrup, Mounds View, MN (US); Peng Li, Palo Alto, CA (US)

Correspondence Address: MERCHANT & GOULD PC, P.O. BOX 2903, MINNEAPOLIS, MN, 55402-0903, US

(21) Appl. No.: 10/226,998

(22) Filed: Aug. 22, 2002

Related U.S. Application Data
(60) Provisional application No. 60/314,108, filed on Aug. 22, 2001.

(51) Int. Cl. H03D 1/00; H04L 27/06

(52) U.S. Cl. 375/342

(57) ABSTRACT

A system that measures a segment of a waveform by isolating the segment by virtue of gating. A waveform anomaly may be gated. The gated waveform is supplied to a plurality of frequency information extractors, which yield information regarding the frequency content of the gated waveform at individual frequencies. Distortion introduced into the gated waveform may be measured by applying the same gating function to a reference waveform. The system may measure or gate an incoming waveform at time intervals dictated by a clock signal recovered from the incoming waveform. A segment of the waveform to be measured may be circulated through a fiber loop, with a fraction of the circulated signal split off for presentation to a measurement system with each circulation. The point in time at which the waveform crosses a threshold may be determined by straddle sampling.

### RELATED APPLICATIONS

This application claims priority of U.S. provisional application Serial No. 60/314,108, filed Aug. 22, 2001 and entitled “METHOD AND APPARATUS FOR MEASURING A WAVEFORM,” which is hereby incorporated by reference in its entirety.

### FIELD OF THE INVENTION

The present invention relates to an apparatus for signal analysis. In another aspect, the invention relates to a method for analyzing a signal.

### BACKGROUND OF THE INVENTION

Much of electrical circuit design has to do with the design and construction of data communication paths. Whether the communication path is between a memory and a microprocessor in a personal computer or it is between two end nodes of a submarine optical communication link, signal integrity is important. Waveform analysis equipment is used to measure the amplitude of waveforms that are transmitted and received over these communication paths. Typically this equipment utilizes some form of amplitude or time sampling in conjunction with time and amplitude references to recreate the waveform amplitude as a function of time. The resulting recreated waveforms are used to determine the performance of these transmission paths and their suitability to transmit data.

Two predominant forms of sampling are in use in the industry for measuring waveforms with regard to electrical or optical signals in the time domain. One method measures time when a predetermined waveform amplitude is reached. The other measures an amplitude at a predetermined time. Both methods yield one discrete time-amplitude value pair related to the waveform per measurement. The goal of both methods is to make an instantaneous measurement. That is, the time or amplitude span over which the waveform is considered for a measurement should be as small as possible so as to avoid measurement error. Acceptable time and amplitude spans are bounded by the rate of change of the waveform amplitude with respect to time.

A waveform can be represented by taking a sequence of measurements in time (sequential sampling). If the rate at which the measurements are taken is much faster than the rate of change of the waveform, then a good representation of the waveform can be produced. If, however, the rate at which the waveform changes is about the same rate or faster than the measurement systems ability to take measurements, a good representation of the waveform cannot be achieved.

In the case of periodic or repetitive waveforms another method of waveform representation can be employed. This method, commonly referred to as repetitive sampling, involves making measurements at various times after a trigger event. The trigger event is an event that happens at the repetition rate of the periodic waveform. A schedule of time values is constructed and measurements are taken according to this schedule with one measurement corresponding to one trigger event. The corresponding table of time and amplitude measurements provides a representation of the waveform.

### BRIEF DESCRIPTION OF THE DRAWINGS

The invention may be more completely understood in consideration of the following detailed description of various embodiments of the invention in connection with the accompanying drawings, in which:

FIG. 0 illustrates a waveform measurement system according to an embodiment of the present invention;

FIG. 1 illustrates a waveform measurement system according to an embodiment of the present invention;

FIG. 2 illustrates an embodiment of a serial data marker generation circuit according to the present invention;

FIG. 3 illustrates another embodiment of a serial data marker generation circuit according to an embodiment of the present invention;

FIG. 4 illustrates an embodiment of a bit clock recovery circuit according to the present invention;

FIG. 5 illustrates an embodiment of an arming/gating circuit according to the present invention;

FIG. 6 illustrates a waveform measurement system according to another embodiment of the present invention;

FIG. 7 illustrates a waveform measurement system according to another embodiment of the present invention;

FIG. 8 illustrates an error measurement circuit according to an embodiment of the present invention;

FIG. 9 is an exemplary flow diagram illustrating steps performed by analysis program according to the present invention;

FIG. 10 illustrates an exemplary computing system according to the present invention;

FIG. 11 illustrates an embodiment of a jitter measurement circuit according to the present invention;

FIG. 12 illustrates another embodiment of a jitter measurement circuit according to the present invention; and

FIG. 13 illustrates another embodiment of a jitter measurement circuit according to the present invention.

FIG. 14 illustrates an embodiment of an optical recirculation system according to the present invention.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention.

### DETAILED DESCRIPTION

The present invention is believed to be applicable to methods and devices for measuring a waveform. While the present invention is not so limited, an appreciation of various aspects of the invention will be gained through a discussion of the examples provided below.

Methods and devices for measuring a waveform are provided for situations relating to when signals are repetitive or not. A waveform is a signal, optical, electrical, or otherwise, with an amplitude that is varying as a function of time. The waveform can be said to contain features. Features are temporally distinct events that are considered to be of significance as related to the quality or characteristics of the waveform. A feature has an optimal amplitude contour with respect to time for each application. Examples of features can be transitions from one logical state to another, overshoot or pre-shoot, ringing, a change in carrier phase or frequency, a signal crossing a specific voltage threshold, etc. Features and the relationship between features are of great interest in the analysis of waveforms. A measurement is the smallest data acquisition that results in some information about a waveform. Examples can be a single amplitude conversion of an analog to digital converter that results in one point on a waveform or a one-shot time measurement.

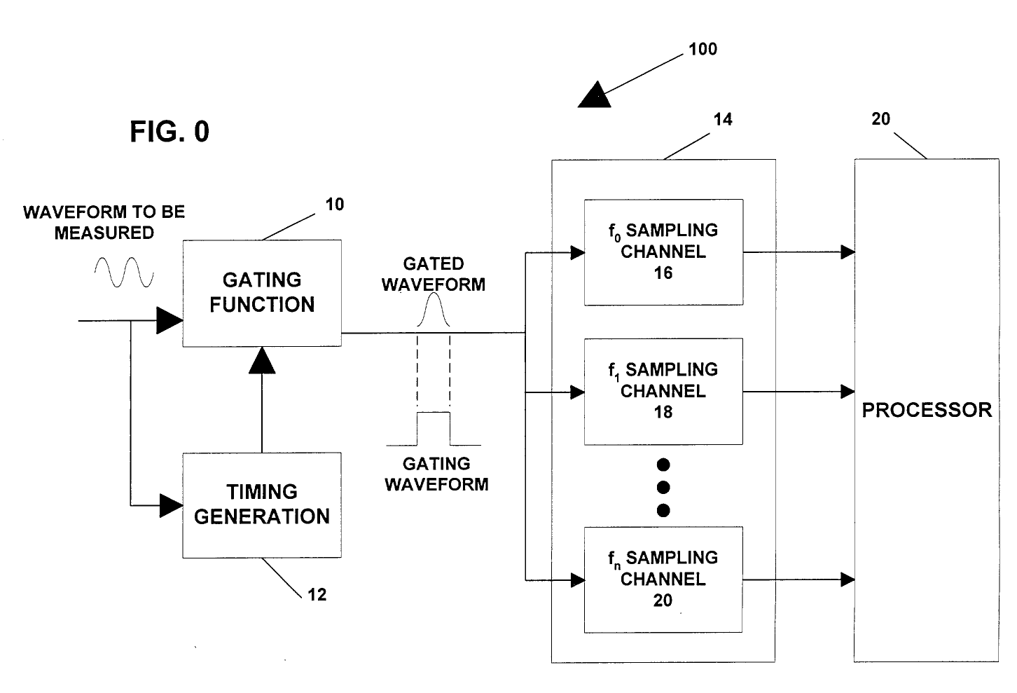

An exemplary waveform measurement system 100 is illustrated in FIG. 0. In general, an initial step in measuring a waveform according to the various embodiments of the invention is to sample or gate through a portion of a waveform under consideration over a small but non-instantaneous period of time. The duration of the gating or sampling window in time is related to the duration of the feature of interest. The waveform to be measured is provided to a gating function 10 under the control of a timing generation circuit 12. The timing generation circuit 12 can be enabled by an internal signal (shown) such as a bit clock or by an external signal (not shown). The gating waveform can be synchronized to the waveform with synchronization circuitry including serial data recognition circuitry and bit clock recovery circuitry. Other types of trigger and time-based circuitry can be used.

The result of the gated waveform is sampled in the frequency domain by one or more frequency sampling blocks 14. The frequency sampling block 14 can include f₀ frequency sampling channel 16, f₁ frequency sampling channel 18, through fₙ frequency sampling channel 18. An amplitude, series of amplitudes, or amplitudes and phases of the various frequency components can then be determined. The number of frequency components that must be determined is based on the type of analysis that is to be performed.

Frequencies f₀ through fₙ may be determined based upon the duration of the gating function 10. For example, f₀ through fₙ may be harmonics of a frequency less than or equal to the reciprocal of the gating duration. This arrangement is particularly useful if the system is to be used to arrive at Fourier coefficients from which the gated waveform is to be reconstructed. A Fourier analysis is but one of many schemes for reconstructing the gated waveform. Accordingly, the frequencies f₀ through fₙ need not be evenly spaced. Assuming that each frequency sampling channel (also referred to herein as a “frequency information extractor”) actually returns information concerning a frequency band, as is the case if each frequency sampling channel takes the form of a band-pass filter, it is unnecessary for each frequency band to be of the same bandwidth. Finally, each frequency sampling channel may return amplitude and phase information regarding of the gated waveform with respect to a basis function other than a sinusoid. For example, the frequency sampling bank 14 may be designed to make use of a wavelet basis function.

Once these frequency components have been determined, the portion of the waveform that was gated through can then be reconstructed mathematically via a transform such as an inverse Fourier transform by software that can be executed by a processor 22. Stated broadly, the information yielded by the frequency sampling bank 14 can be used to arrive at a time-based function that re-creates the gated waveform. In general, the resulting measurement is an inverse Fourier transform of a one-time event. The resulting reconstructed waveform represents the entire portion of the original waveform over the gating or sampling time interval. The signal may be graphically reproduced by using a plurality of time values as arguments of the aforementioned time-based function, and plotting the outcome of such a calculation against an axis representing time.

In the context of data communications, a one Unit Interval (UI) time represents the amount of time that is required to send one bit of information. In some embodiments of this invention a one UI segment of the waveform can be measured. In other embodiments, more or less than one UI can be measured. The gating function produces a waveform that is the multiplication of the gating pulse and the waveform that is to be measured. The resulting waveform is then conveyed to a bank of frequency decomposition channels where the amplitude, or amplitude and phase, of the frequency components are evaluated. This can be done by amplitude detection, quadrature detection, digital signal processing, or other known techniques.

A gating waveform that is approximately one UI wide can use circuitry similar to that used to generate the serial data in data communications systems. Also, in some embodiments, the error of the gate signal circuitry does not add in to the time measurement error. The measurement apparatus according to the present invention allows the acquisition of an entire feature within a time window.

In the context of data communication signals and waveform jitter measurements where transient “one-time” events are of great concern, it is desirable to be able to measure a portion of a waveform rather than just one point on that waveform. The ability to measure a portion of the waveform provides all of the information that is needed to determine the important characteristics related to signal quality and ultimately bit error rate.

The bit error rate of a communication system is a the ratio of bit errors that occur to the number of data bits sent, and is the primary metric of how well that system is working. Prediction and evaluation of bit error rate is the primary application for test equipment in the context of datacom.

The receiver at the end of a communication channel evaluates the incoming data stream on a one UI basis. Eye diagrams, a widely used analysis form for serial data communications, present a time unified view of all of the data transitions in a data waveform by overlaying them on a one UI time period. Many bit error rate analysis methods normalize time to one UI.

Embodiments of the waveform measurement system 100 can provide several different types of evaluations that can be used to support the application of bit error rate analysis. The distribution of where the data transitions occur and amplitude and timing jitter can be used to predict the bit error rate of the system. One category is feature evaluation which is concerned with the contour of a single feature typically in relation to some ideal expected contour. Feature evaluation can be very straightforward because features such as overshoot/pre-shoot, transition time and amplitude can be made with one measurement. Another evaluation category is comparative feature analysis. This is comprised of multiple features evaluations and how they relate to each other. Eye diagrams are an example of comparative feature analysis where the data waveform is displayed in relation to a one UI time period. One way to use an eye diagram is to superimpose the transitions in the data stream on top of each other.

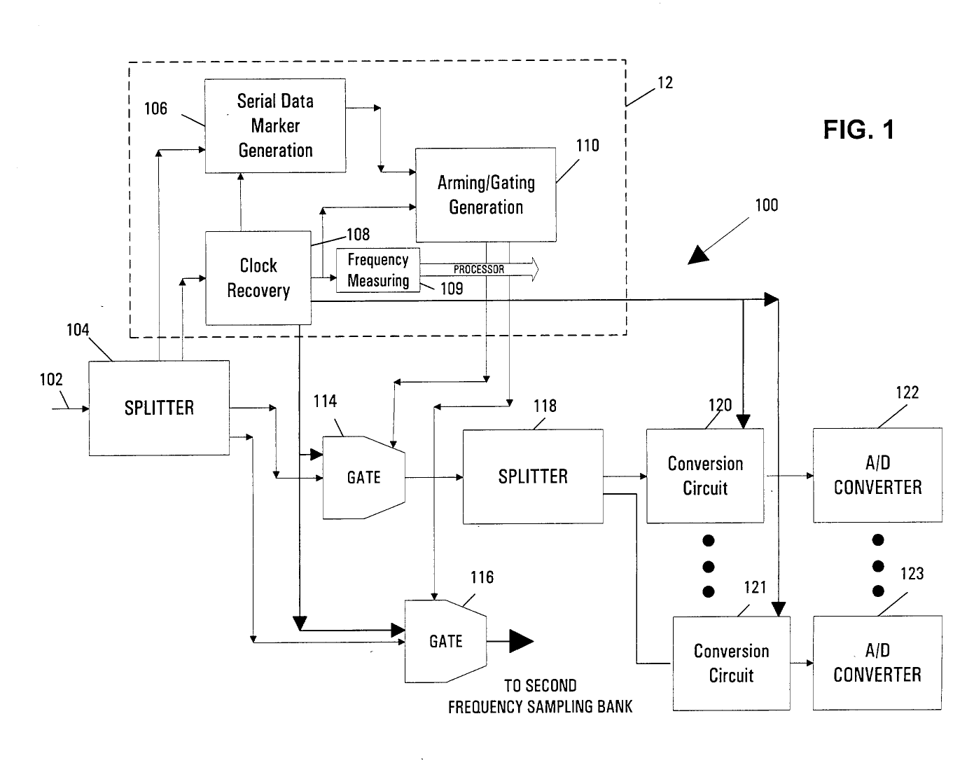

FIG. 1 is an exemplary waveform measurement system 100 according to the present invention. Waveform measurement system 100 includes a splitter 104 and a timing generation circuit 12. The timing generation circuit can include a serial data marker generation circuit 106, a clock recovery circuit 108, frequency measuring circuit 109, and an arming/gating circuit 110. The waveform measurement system includes gates 114 and 116, splitter 118, conversion circuits 120 and 121 and analog to digital conversion circuits 122 and 123. Data signal 102 is provided to a splitter 104. The splitter 104 can include a high bandwidth splitter, filter, and amplification. In this embodiment, the splitter 104 splits the input signal 102 into four channels which are provided to the serial data marker generation circuit 106, the clock recovery circuit 108, and gates 114 and 116. Gates 114 and 116 are typically FETs or diode bridges.

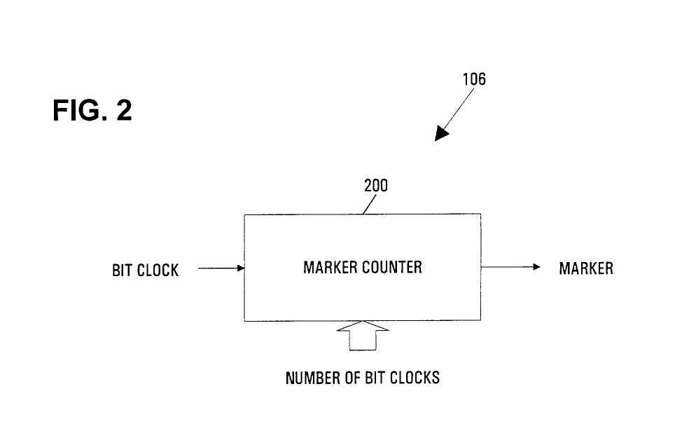

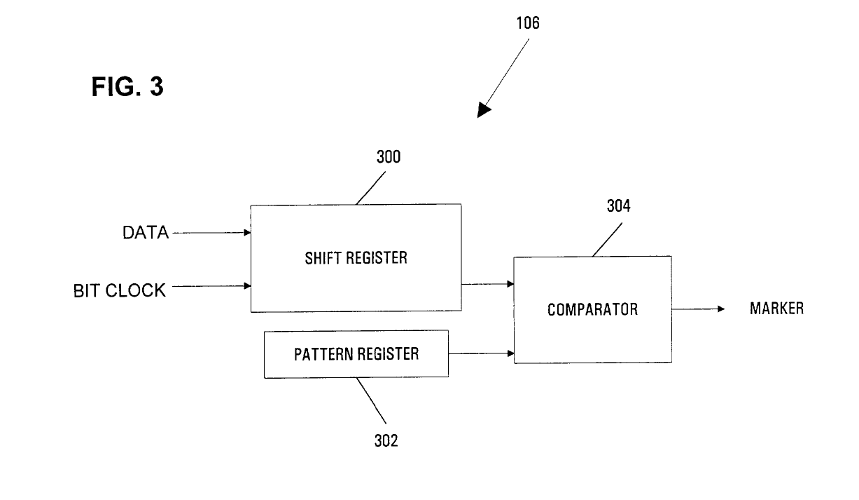

Serial data marker generation circuit 106 recognizes the data signal 102 so that a trigger can be issued so as to observe a particular portion of the waveform. This can be done in a variety of ways. FIG. 2 is an exemplary serial data marker generation circuit 106 according to one embodiment of the present invention. If the serial data has a repeating pattern and the pattern length is known, a counter 200 running off of the bit clock can be set to create an event (marker) that will occur at the same time in each pattern. FIG. 3 is an exemplary serial data marker generation circuit 106 according to another embodiment of the present invention. Circuit 106 includes a shift register 300, a register 302, and a comparator 304. The incoming data is provided to a shift register 300 which is triggered by the bit clock. The comparator 304 compares the data stored in the shift register 300 with data that is stored in a register 302 to generate a marker when coincidence is achieved.

The pattern synchronization functionality could take a variety of forms. It could be as simple as a programmable counter that is loaded with the pattern length and clocked by the recovered bit clock. The terminal count of this counter would provide a pattern marker that tracks the pattern. This would be useful in applications involving clock analysis. A digital comparator at the output of the counter could be used to generate time offsets for initiating measurements at different bit positions in the pattern. A data stream compare function could allow more functionality in that it could enable measurements based on variable length compares.

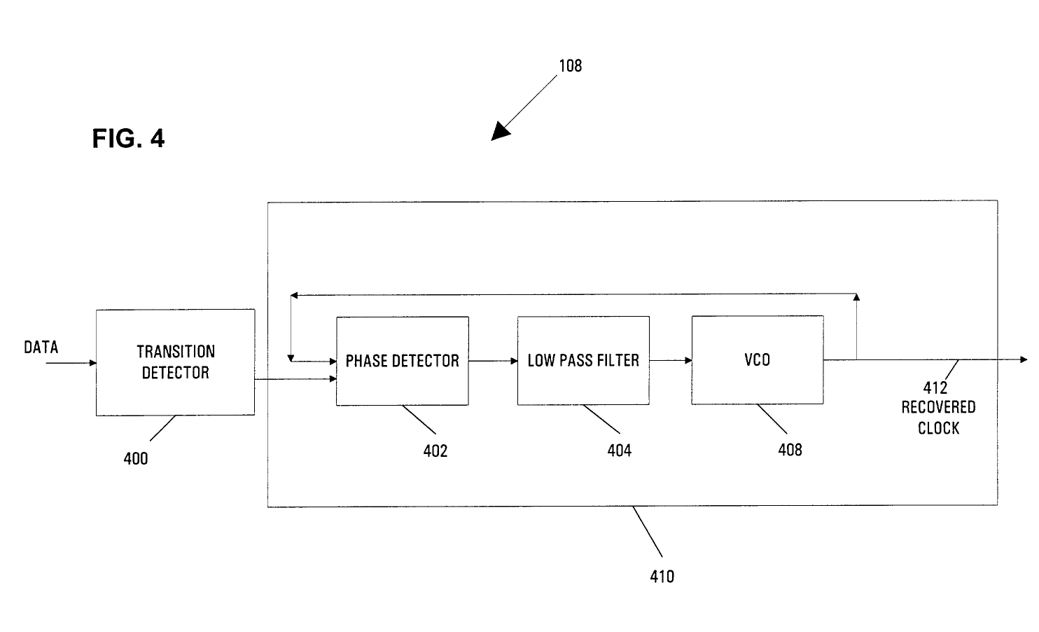

In some embodiments, the clock recovery circuit 108 recovers the bit clock from the incoming data signal. In other embodiments the bit clock is not recovered. This bit clock is used to enable the measurement of the waveform. FIG. 4 illustrates an exemplary bit clock recovery circuit according to the present invention. The bit clock recovery circuit 108 includes a transition detector 400 and a PLL 410. The transition detector 400 outputs a pulse at each transition in the data. The PLL 410 can include a phase detector 402, low-pass filter 404, and a voltage controlled oscillator (VCO) 408. The incoming data is provided to a transition detector 400 coupled to the PLL 410.

The bit clock has, by definition, a period of one UI. The bit clock is the time base used by a receiver to sample the data waveform for recovering the data. The relationship between bit clock and data, along with other factors, are what ultimately defines the bit error rate of the system. If a high quality clock can be generated that tracks the bit clock for the data stream, it can be used in a system for taking measurements of a data waveform. Using a recovered bit clock can make the measurement system much more straightforward because measurement activities can be related directly to this one UI period. The bit clock can also be provided to the frequency sampling portion of the waveform measurement system 100. The bit clock may also be multiplied so that a measurement system (such as measurement system 100 or a sampling unit) operates based upon a clock running at a frequency that is a multiple of the frequency of the recovered bit clock. Thus, for example, a measurement system may take ten measurements per bit, with each measurement known to stand in a defined relation to the bit. Multiplication circuits are known in the art and are therefore not presented herein. Using a bit clock pseudo time base allows direct measurement of data related events without the intermediate steps of first relating each event to an independent time standard. The recovered bit clock frequency can be related to an absolute frequency standard in order to produce more accurate measurements.

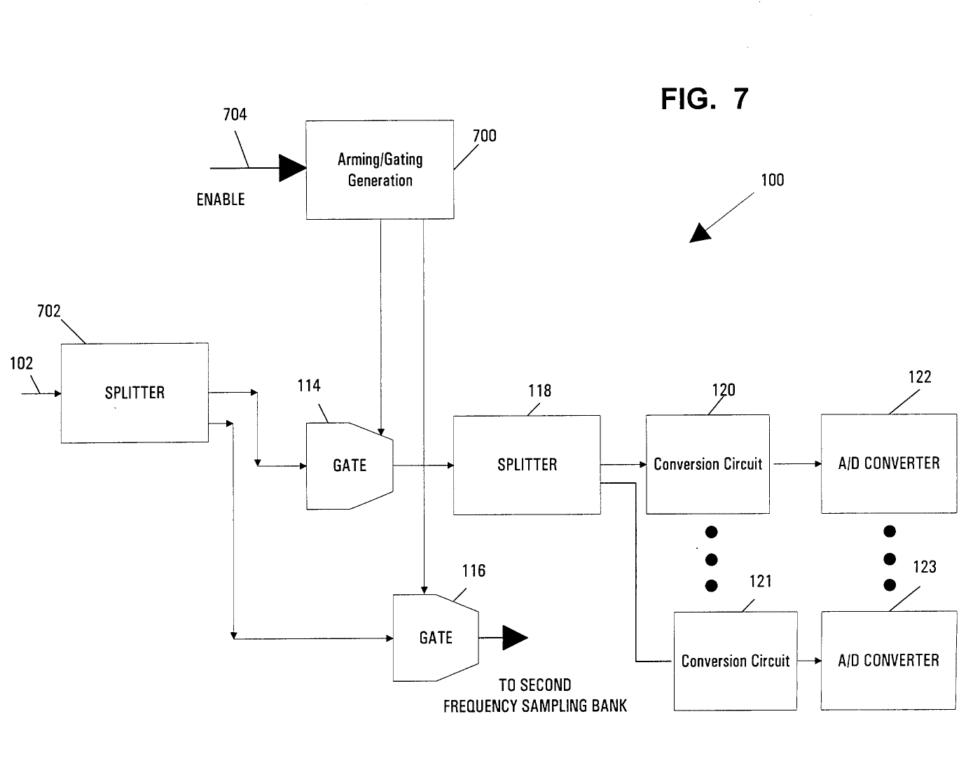

The waveform measurement system 100 shown in FIG. 1 illustrates an embodiment where the bit clock is used as the time reference (bit clock as a trigger) for the measurements. In other embodiments, such as the embodiment of FIG. 7, the bit clock is not recovered from the data stream. When the bit clock is recovered, it can be used in a variety of ways in the waveform measurement system 100. The recovered bit clock can be provided to the frequency sampling bank(s) as a frequency reference. Depending on the type of conversion that is used for this function, the bit clock or frequencies derived off of it can be used to determine the amplitude or amplitude and phase of various frequency components of the gated signal. Providing the bit clock to the frequency analysis circuitry can reduce the system error.

The bit clock can be used in the generation of the gating window. For example, the bit clock can be provided to the arming/gating generation circuit 110. The bit clock can also be provided to gates 114 and 116.

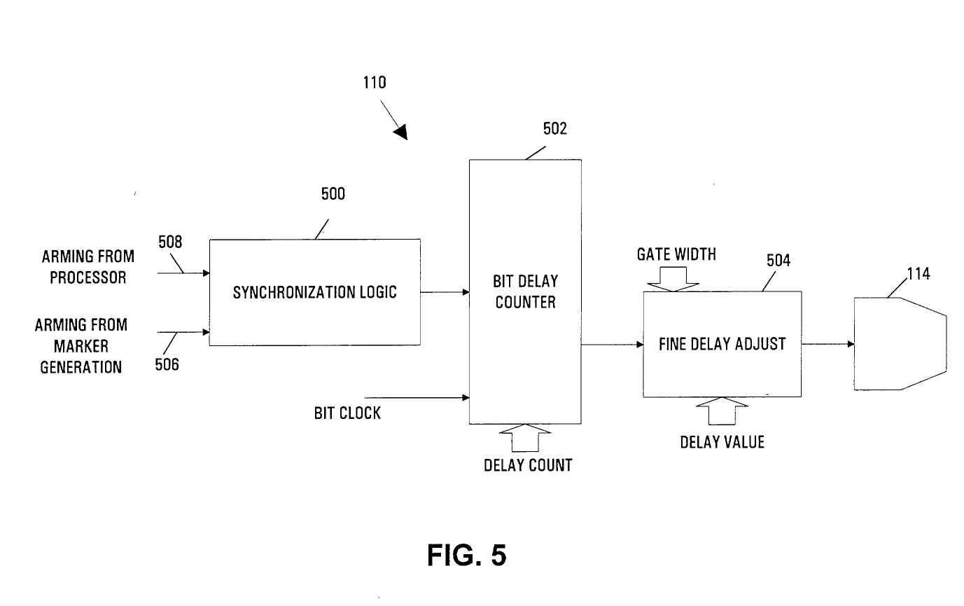

Arming/gating generation circuit 110 provides the gating signal function for the gates 114 and 116. FIG. 5 illustrates an exemplary arming/gating generation circuit according one embodiment of the present invention. Arming/gating generation circuit 110 includes synchronization logic 500, counter 502, and delay 504. The Arming/gating generation circuit 110 causes a measurement to take place at the time of interest relative to the waveform being observed. In one embodiment, the Arming/gating generation circuit 110 provides the enable signal to the gate 114. The synchronization logic 500 processes information about the waveform and the needs of the application that will dictate what information is required by the arming function in order to cause the measurement to be initiated at the appropriate time. The synchronization logic 500 can receive an arming signal 508 from the processor and an enable signal 506, which can be provided by the marker generation circuit 106. The synchronization logic 500 is programmed to provide a count enable signal to the counter 502 at the appropriate time since the processor is likely to be asynchronous with the enable signal 506 events. The count enable signal 506 can always be enabled, can enable based on the serial data marker generation circuit 106, can enable based on bit clock recovery circuit 108, can enable based on a pattern repeat, or can enable based on other events. The enable events can be alone or in combination with other events.

There are a variety of events that can enable waveform measurements. The pattern synchronization functionality described previously was an example. In other embodiments an anomaly snapshot feature measurement is provided. The architecture that supports this application uses an anomaly recognition function to determine if a particular anomaly has occurred. An anomaly could be a bit error (e.g., the bit is malformed or otherwise errant), signal overshoot, a slow rise or fall time, transition density, amplitude, polarization state or any other event that is considered anomalous and/or detectable and can be instrumented to cause a trigger event.

An anomaly may be detected by defining one or more boundaries on a Cartesian plane, wherein one axis represents signal level and the other axis represents time. If a waveform, when plotted upon the Cartesian plane, falls outside the one or more boundaries, the waveform is determined to be anomalous. For example, a non-anomalous waveform may have a particular amplitude, a, at a certain time, t. The point defined by the ordered pair <t, a> may be examined to determine whether or not it falls on a particular side of a boundary. Depending on the side of the boundary the point <t, a> falls on, the point will be determined to be anomalous or normal. Alternatively, a pair of points may be examined, to determine their relationship to two or more boundaries. For example, a waveform may be determined to be anomalous if a first point lies within a first bounded area and a second point lies within a second bounded area. Further, a waveform may be determined to be anomalous if a first and second point both lie within a bounded area, or if they fail to lie within a bounded area. Still further, a waveform may be determined to be anomalous if neither a first point lies within a first bounded area, nor a second point lies within a second bounded area.

Fast, infrequent measurements can be difficult to observe because many measurements of the event must be taken to build up a representation of a feature. An example of this would be observing a data waveform with a 10⁻¹² bit error rate at a high data rate of 10 gigabits per second. In this case a bit error would occur one every 1.6 minutes one the average. If it took 100 measurements to fill out a feature, it would take about 2 hours and 45 minutes to recreate the feature related to this bit error. This assumes that the cause of the error is systematic and that repetitive sampling as known in the art will have a chance to “build up” a representation of this repeating feature. Embodiments of this invention provide for the acquisition of the feature with a single measurement which could take on the order of tens of microseconds. For this example, this corresponds to a 1 billion times increase in measurement rate. For embodiments of this invention, extremely rare features can be captured with only one occurrence of the feature.

Arming/gating generation circuit 110 creates a gating signal with appropriate rise time and signal quality. In one embodiment, the clock recovery circuit 108 provides the bit clock to the gate. In other embodiments the gate can be enabled by an internal clock. The gates 114 and 116 typically comprise a FET or a diode bridge, as is known in the art. The pulse is provided from the arming/gating generation circuit 110 to gates 114 and 116. An entire segment of the waveform of interest can be extracted. Although two gates 114 and 116 are shown, those skilled in the art will recognize that other embodiments can use more or less switches and the accompanying circuitry. With respect to gates 114 and the first frequency sampling bank, the output signal conditioning circuit 118 splits the signal into certain frequency components (f₀, f₁, . . . fₙ). The conversion circuits 120 determine characteristics of the frequency components such as amplitude and phase in order to reconstruct the signal. The conversion circuits 120 can include in-phase and quadrature demodulators or a mixer and low pass filter (demodulation done in the processor), or other demodulation methods. A Hilbert transformation, or other method, can be used to estimate in-phase or quadrature components using the processor. The converted signal is provided to analog to digital conversion circuits 122.

In the embodiment of FIG. 1, the bit clock recovery circuit 108 provides the bit clock to the arming/gating generation circuit 110. This provides a frequency reference for measuring the amplitude and/or phase of the frequency components. Using the recovered bit clock can reduce the error that can be introduced by the gating window placement. If the window is moved, then the frequency components stay the same relative to the bit clock. In other embodiments, other means are provided to activate the arming/gating generation circuit 110, as is known in the art.

The recovered bit clock can be provided to a frequency measuring circuit 123 that provides scaling of time measurement values and/or verifies that the recovered bit clock frequency is satisfactory. A typical frequency measuring circuit 123 can include a frequency counter and a precision time base.

The conversion circuits 122 can be connected to computing device that operates under the control of an analysis program. A computing device, such as computing system, typically includes at least some form of computer-readable media. Computer readable media can be any available media that can be accessed by the computing system. By way of example, and not limitation, computer-readable media might comprise computer storage media and communication media.

Computer storage media includes volatile and nonvolatile, removable and non-removable media implemented in any method or technology for storage of information such as computer readable instructions, data structures, program modules or other data. Computer storage media includes, but is not limited to, RAM, ROM, EPROM, flash memory or other memory technology, CD-ROM, digital versatile disks (DVD) or other optical storage, magnetic cassettes, magnetic tape, magnetic disk storage or other magnetic storage devices, or any other medium that can be used to store the desired information and that can be accessed by the computing system.

Communication media typically embodies computer-readable instructions, data structures, program modules or other data in a modulated data signal such as a carrier wave or other transport mechanism and includes any information delivery media. The term “modulated data signal” means a signal that has one or more of its characteristics set or changed in such a manner as to encode information in the signal. By way of example, and not limitation, communication media includes wired media such as a wired network or direct-wired connection, and wireless media such as acoustic, RF, infrared, and other wireless media. Combinations of any of the above should also be included within the scope of computer-readable media. Computer-readable media may also be referred to as computer program product.

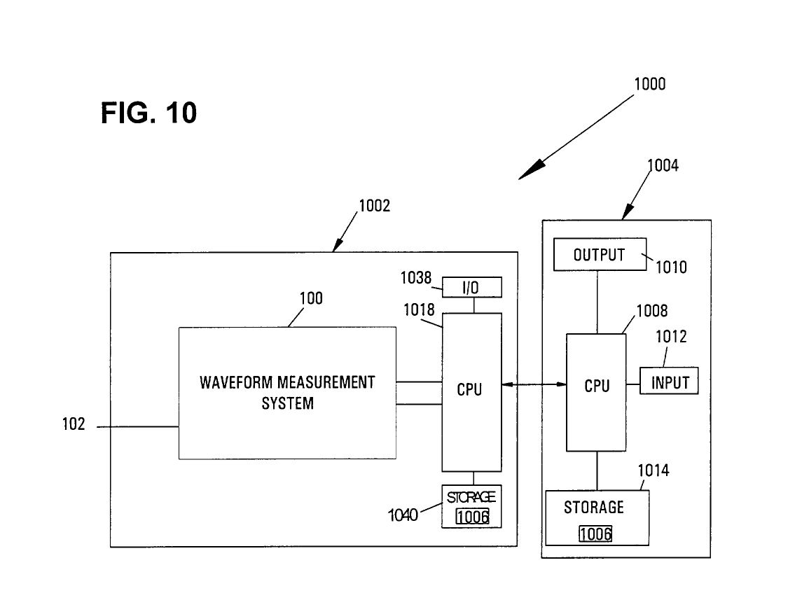

FIG. 10 illustrates an exemplary computing system 1000 according to the present invention. A workstation 1004 operates under the control of an analysis program 1006 resident on the workstation 1004. The analysis program 1006 is typically implemented through data analysis software. One commercially available analysis software is the Wavecrest Virtual Instrument (VI) software, available from Wavecrest Corporation, Eden Prairie, Minn. The workstation 1004 comprises a processor 1008 and a memory including random access memory (RAM), read only memory (ROM), and/or other components. The workstation 1004 operates under control of an operating system, such as the UNIX® or the Microsoft® Windows NT/2000 operating system, stored in the memory to present data to the user on the output device 1010 and to accept and process commands from the user via input device 1012, such as a keyboard or mouse.

The analysis program 1006 is preferably implemented using one or more computer programs or applications executed by the workstation 1004. Those skilled in the art will recognize that the functionality of the workstation 1004 can be implemented in alternate hardware arrangements, including a configuration where the measurement apparatus 1002 includes CPU 1018, memory 1040, and I/O 1038 capable of implementing some or all of the steps performed by the analysis program 1006. Generally, the operating system and the computer programs implementing the present invention are tangibly embodied in a computer-readable medium, e.g. one or more data storage devices 1014, such as a ZIP® drive, floppy disc drive, hard drive, CD-ROM drive, firmware, or tape drive. However, such programs may also reside on a remote server, personal computer, or other computer device.

The analysis program 1006 provides for measurement/analysis options and measurement sequences. The analysis program 1006 can interact with the waveform measurement system 100 through the on-board CPU 1018.

The logical operations of the various embodiments of the present invention are implemented (1) as a sequence of computer implemented acts or program modules running on a computing system and/or (2) as interconnected machine logic circuits or circuit modules within the computing system. The implementation is a matter of choice dependent on the performance requirements of the computing system implementing the invention. Accordingly, the logical operations making up the embodiments of the present invention described herein are referred to variously as operations, structural devices, acts or modules. It will be recognized by one skilled in the art that these operations, structural devices, acts and modules may be implemented in software, in firmware, in special purpose digital logic, and any combination thereof without deviating from the spirit and scope of the present invention.

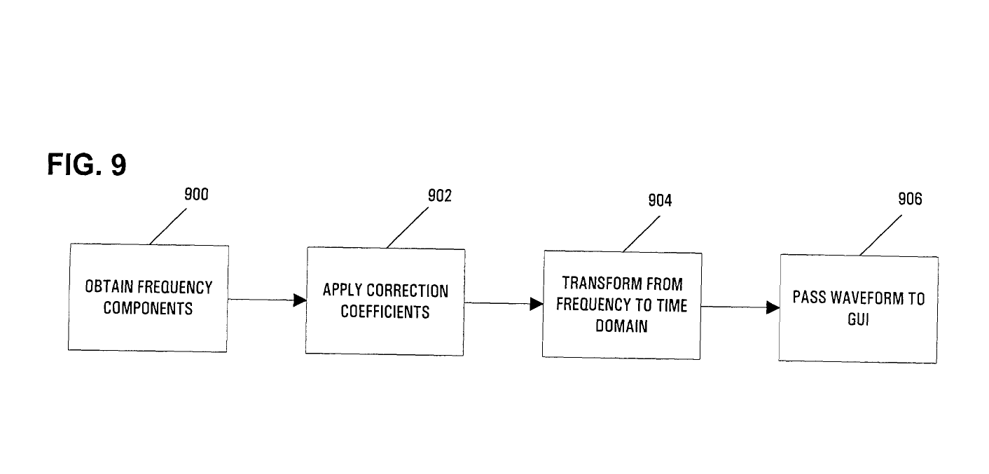

FIG. 9 is an exemplary flow diagram illustrating steps performed by the analysis program 1006 according to the present invention. Module 900 represents the analysis program 1006 obtaining the frequency components from the frequency sampling banks. Typically this would be the magnitudes or magnitudes and phases of the channel. Module 902 represents the analysis program 1006 applying correction coefficients to the frequency components. In other embodiments, the analysis program 1006 can alter hardware characteristics to make the coefficient adjustments. The correction coefficients can correct non-ideal system component related errors and/or force the overall system response. System component errors can include differential phase and magnitude errors associated with the conversion circuits or o/e converters. The correction coefficients can force the system to an overall desired system response. For example, the correction coefficients can be used to force the system to have the transient response of a four-pole Bessel-Thompson low pass filter for data communications applications. Module 904 represents the analysis program 1006 transforming from the frequency to the time domain based on the results from the frequency channels. One method is an inverse Fourier transform. Other methods include summing a Fourier series. Module 906 represents the analysis program 1006 passing the waveform to the graphical user interface (GUI).

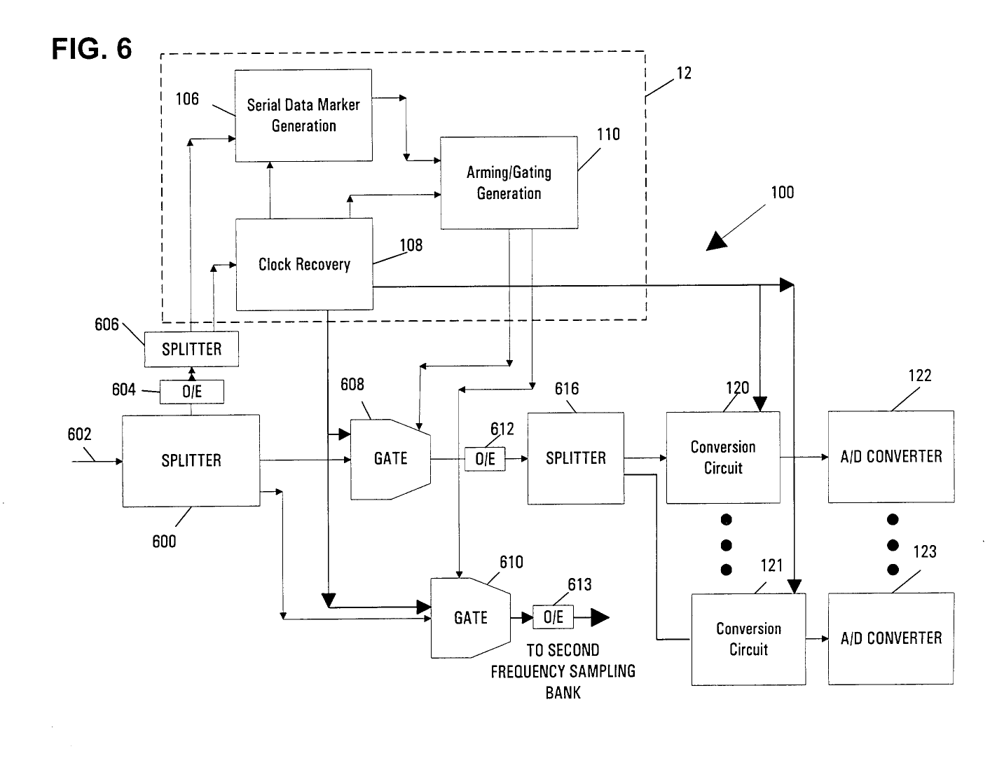

FIG. 6 is an exemplary waveform measurement system 100 according to another embodiment of the present invention. Waveform measurement system 100 includes an optical splitter 600, optical modulators (gates) 608 and 610, optical to electrical (O/E) converters 612 and 613, splitter 616, O/E converter 604, splitter 606, timing generation circuit 12 (which can include serial data marker generation circuit 106, clock recovery circuit 108, and arming/gating generation circuit 110), conversion circuits 120 and 121, and analog to digital converter circuits 122 and 123. The waveform measurement system can include an optical amplifier coupled to an optical isolator. The optical amplifier typically consists of fiber that is doped with erbium and a pump LASER that supplies energy to the system. The splitter 600 is functionally similar to electrical couplers and can be made of fibers twisted together or planar waveguides. The optical modulators 608 and 610 are similar to ones used to a modulate data signal at the transmitter when used in a data transmission system. These are typically lithium niobate—Mach Zender interferometric modulators. The O/E 612 converter can consist of a photodiode followed by some amplification (usually in the form of a transimpedance amplifier). Those skilled in the art will recognize that other arrangements of the modulators, splitters, o/e converters, and other components can be used to implement waveform measurement system 100.

FIG. 7 is an exemplary waveform measurement system 100 according to another embodiment of the present invention. Waveform measurement system 100 includes a splitter 702, gates 114 and 116, arming/gating generation circuit 700, splitter 118, conversion circuits 120 and 121, and analog to digital conversion circuits 122 and 123. Enable signal 704 is provided to the arming/gating generation circuit 700. Accordingly, there can be errors caused by the arming/gating generation circuit 700. In other embodiments, the gates 114 and 116 can be enabled by a traditional oscilloscope time base, which can include a trigger circuit and a programmable time delay, as is known in the art.

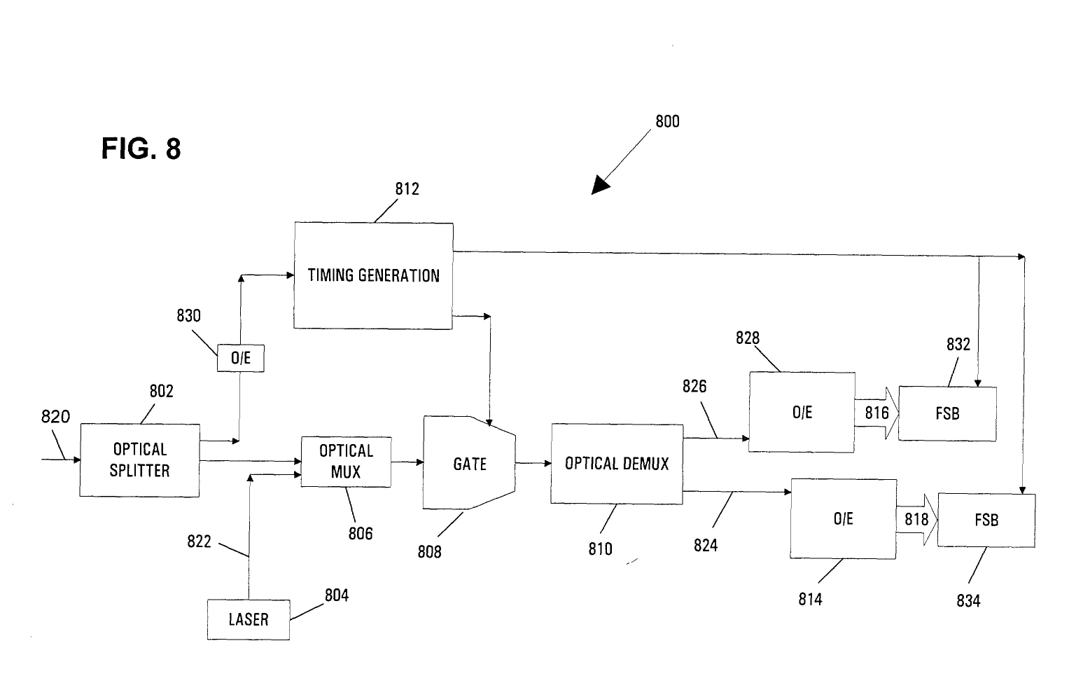

FIG. 8 is an embodiment of an error measurement circuit 800 according to the present invention. The embodiment of FIG. 8 illustrates a wavelength multiplexing technique for compensating for error. Those skilled in the art will recognize that other circuits can be used, including electrical circuits or circuits that are time based. Error measurement circuit 800 includes an optical splitter 802, arming circuit 812, continuous wave (CW) laser 804, multiplexer 806, optical modulator 808, optical demultiplexer 810, and o/e converters 814. Input signal 820 having a wavelength of λ₁ is coupled to a reference laser signal 822 having a wavelength λ₂. The optical modulator 808 is enabled by timing generation circuitry 812. The optical demultiplexer 810 separates the reference signal 824 having a wavelength λ₂ from the sampled signal 826 having a wavelength of λ₁. The o/e converters 814 and 828 provide the sampled signal 816 and the reference signal 818 to frequency sampling banks 832 and 834. The frequency sampling banks 832 and 834 may be coupled to a microprocessor (not depicted) or integrated circuit (not depicted), so that the information yielded by the banks 832 and 834 can be used for correcting distortion introduced to the sampled signal 816 by the gate 808. Those skilled in the art will recognize that error measurement circuit 800 can be implemented with electrical components instead of the optical components, or a combination of both.

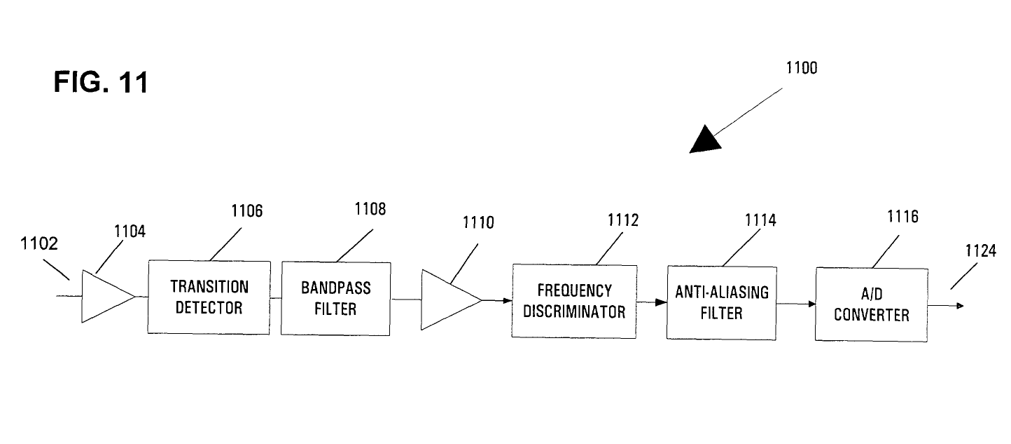

In methods and apparatus for signal analysis, it can be beneficial to recover the bit clock of the incoming signal and use it as the measurement time base. That can remove the error of the bit clock from signal analysis measurement equipment. It can also be beneficial to measure the jitter associated with the signal. FIG. 4 illustrates one embodiment of a bit clock recovery circuit according to the present invention. FIG. 11 illustrates an embodiment of a jitter measurement circuit 1100 according to the present invention. Jitter measurement circuit 1100 can be coupled to the splitter 104 in the embodiment of FIG. 1. Alternatively, the jitter measurement circuit 1100 from any other serial communications signal. The jitter measurement circuit 1100 includes a limiting amplifier 1104, transition detector 1106, narrow bandpass filter 1108, limiting amplifier 1110, frequency discriminator 1112, anti-aliasing filter 1114, and analog to digital converter 1116. The incoming serial data signal 1102 is provided to the limiting amplifier 1104. In this embodiment, narrow bandpass filter 1108 permits signals that are less approximately 10 GHz to pass to the limiting amplifier 1110 for a data rate of 10 GB/s. The limiting amplifiers 1104 and 1110 minimize the amplitude variations in the signal. The frequency discriminator 1112 provides an output voltage which is a function of the instantaneous frequency provided by the limiting amplifier 1110. Signal 1124 can be provided to a workstation that operates under the control of an analysis program resident on the workstation to analyze low and/or medium frequency jitter. Low frequency jitter is typically about 10 Hz to 1 MHz. Medium frequency jitter is typically about 5-10% of the clock frequency. A method and apparatus of analyzing jitter is disclosed in U.S. Pat. No. 6,356,850, “Method and Apparatus for Jitter Analysis” which is herein incorporated by reference for all purposes. As is known in the art, the signal 1124 can be used to perform DSP functions, autocorrelation, FFT, range, peak to peak, mean, standard deviation, statistical information, histograms, and other analyses.

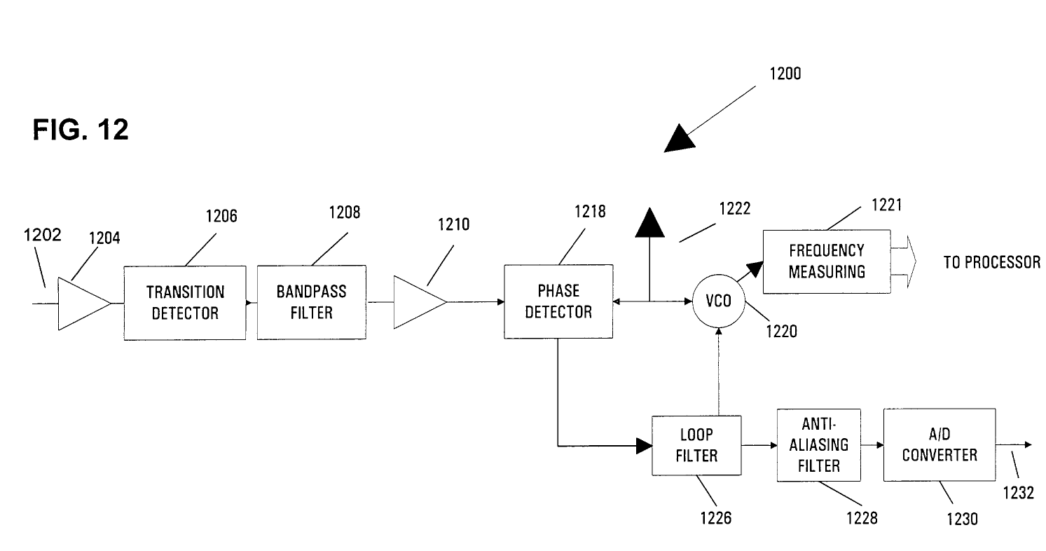

FIG. 12 illustrates an embodiment of a jitter measurement circuit 1200 according to the present invention. The jitter measurement circuit 1200 includes a limiting amplifier 1204, transition detector 1206, narrow bandpass filter 1208, limiting amplifier 1210, a PLL (including phase detector 1218, loop filter 1226, and VCO 1220), frequency measuring circuit 1221, anti-aliasing filter 1228, and analog to digital converter 1230. The incoming serial data signal 1202 is provided to the limiting amplifier 1204. In this embodiment, narrow bandpass filter 1208 permits signals that are approximately 10 GHz to pass to the limiting amplifier 1210 for a data rate of 10 GB/s. Signal 1132 can be provided to a workstation that operates under the control of an analysis program resident on the workstation to analyze low and/or wander. Low frequency jitter is typically about 10 Hz to 1 MHz. Signal 1222 provides the bit clock from the VCO 1220. In the embodiments according to FIG. 1, jitter measurement circuit 1200 can be an embodiment of clock recovery circuit 108 and enable jitter analysis of the input signal 102. The recovered bit clock can be provided to a frequency measuring circuit 1221 that provides scaling of time measurement values and/or verifies that the recovered bit clock frequency is satisfactory. A typical frequency measuring circuit 1221 can include a frequency counter and a precision time base.

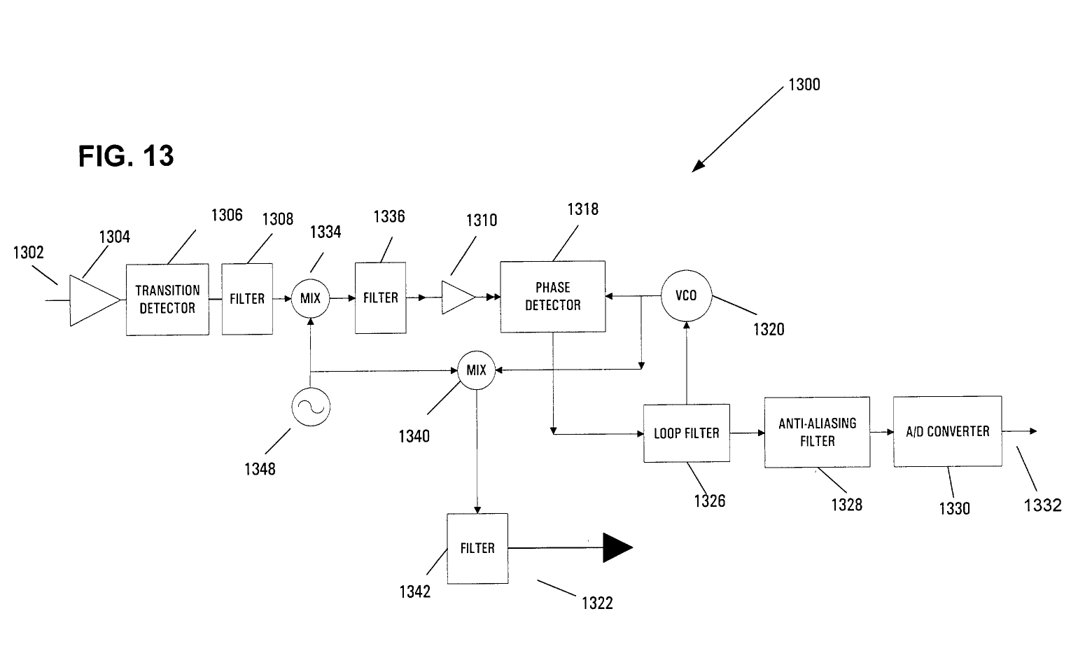

FIG. 13 illustrates another embodiment of a jitter measurement circuit according to the present invention. The jitter measurement circuit 1300 includes a limiting amplifier 1304, transition detector 1306, wide bandpass filter 1308, mixer 1334, clock 1338, narrow bandpass filter 1336, limiting amplifier 1310, a PLL (including phase detector 1318, loop filter 1326, and VCO 1320), anti-aliasing filter 1328, analog to digital converter 1330, mixer 1340, and wide bandpass filter 1342. The incoming serial data 1302 is provided to the limiting amplifier 1304. Wide bandpass filter 1308 typically permits signals greater than 10 GHz to pass to the mixer 1334. Mixer 1334 is driven by the clock 1338 which can be running at 9.5 GHz to reduce the signal to 500 MHz to provide to the PLL. Mixer 1340 increases the signal to 10 GHz and enables wide bandpass filter 1342 to provide a bit clock signal 1322. In the embodiments according to FIG. 1, jitter measurement circuit 1300 can be an embodiment of clock recovery circuit 108. Signal 1332 can be provided to a workstation that operates under the control of an analysis program to analyze low and/or medium frequency jitter.

In some embodiments, the gating function width can be adjusted to optimize the measurement capability. In certain cases such as when one is looking for an amplitude threshold crossing, not as much information is required to make each measurement. The only portion of the waveform that is of interest is the portion that crosses threshold. In this case the measurement sequence could proceed in an adaptive fashion. In general, a wider gating window could be used to get an overview of the waveform in the area of the threshold transition. Once the transition has been located the gating window could be narrowed reducing the number of lower harmonics required for the measurement. If the frequency decomposition channels are agile in frequency, lower harmonic channels can be “re-allocated” to observe higher frequency components allowing agile bandwidth measurements.

In other embodiments, two or more gating heads can be used on one signal path. This can be called “straddle” gating. In the context of using two gating heads on one signal path, the gating time of the two heads can be moved around so as to adaptively home in on a feature of interest. One scheme of straddle measuring involves measuring a repetitive signal at a first point in time, and again at a second point in time, with the intended purpose being to determine the point in time at which the repetitive signal crosses a threshold. The two measurements should straddle the threshold. If they do not straddle the threshold, a subsequent repetition of the waveform may be awaited, at which point, both measurements may be stepped backwards or forwards in time. This process can continue until the measurements straddle the threshold. If neither of the measurements are within a tolerance of the threshold, a subsequent repetition of the signal is waited for. Upon arrival of a subsequent repetition of the signal, both the first and second measurements are stepped toward the point in time at which the signal crosses the threshold. This process is repeated until one of the samples is within a designated tolerance of the threshold.

The above-described scheme may be refined by permitting the threshold value to be selected by a user. Additionally, the increment by which the first and second measurements are stepped toward the threshold-crossing event may be selected, as well.

Straddle gating can avoid having to sample the waveform uniformly at all locations when the points of interest can be confined to a small temporal location. Such uniform gating is useful when an overview of the entire waveform is necessary, but extremely inefficient when the area of interest is confined to a feature in the waveform.

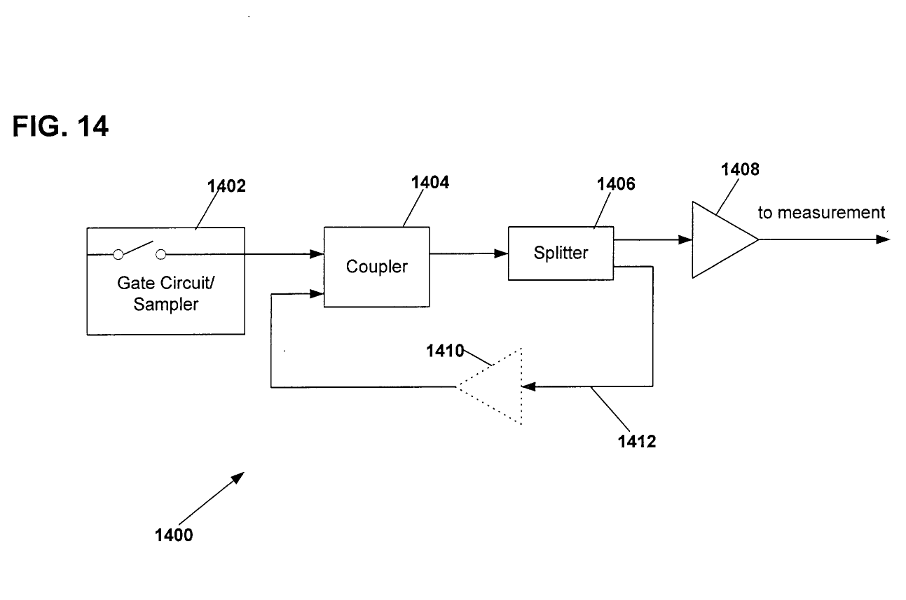

FIG. 14 depicts an embodiment of an optical recirculation system 1400 according to the present invention. The optical recirculation system 1400 achieves the result of iteratively providing a gated waveform to a measurement system. Thus, for example, if an errant bit is isolated for measurement by virtue of gating, the optical recirculation system 1400 literally “replays” the errant bit many times over to a measuring system (not depicted in FIG. 14). The measuring system can then take advantage of the multiple “replays” of the errant bit to accurately measure the bit. The measuring system can take advantage of the multiple “replays” in many ways. For example, the measuring system can measure each of the “replayed” waveforms, and average the many measurements, so as to reduce the error content of the measurements. Alternatively, the measurement system may sample the waveform at a different location with each repetition of the waveform, so as to enhance the sampling density achieved by the measuring system.

The recirculation system 1400 includes a gating circuit 1402 at its front end. The gating circuit 1402 isolates a segment of an optical waveform for recirculation and subsequent measurement. The output of the gating circuit 1402 is coupled to an optical coupler 1404, which possesses a first and second input. The gating circuit 1402 is depicted as being coupled to the first input of the coupler 1404. The coupler 1404 combines signals inputted via its first and second inputs, and yields the combination on its output line. The output line is coupled to a splitter 1406, which possesses a first and second output line. The splitter 1406 yields a fraction of the signal at its input to its first output line and a fraction of the aforementioned signal to its second output line (e.g., 5% to it first output, 95% to its second output). The first output line is coupled to a measurement system (not depicted), by way of an amplifier 1408, if necessary. The second line is connected, via a fiber loop 1412, to the second input of the coupler 1404. An optional amplifier 1410 may be interposed in the fiber loop 1412. The coupler 1404, splitter 1406, fiber loop 1412, and amplifier 1410 cooperate to form a loop in which the gated waveform circulates, with a fraction of the gated waveform being split off and conducted to a measuring system with each circulation.

In order to prevent aliasing, the fiber loop 1412 should have a fiber length, such that an optical wave propagating from one end of the fiber loop 1412 to the other end consumes a period of time greater than the gating duration employed by the gating circuit 1402. Additionally, the amplifier 1410 must use a gain level that is chosen to be high enough to permit the waveform to circulate enough times to prove useful to the measurement system to which the iterative waveform is presented. On the other hand, the amplifier 1410 must use a gain level that is chosen to be low enough, so as not to saturate the fiber loop 1412. Such a gain level is described as being a “suitable gain.”

The above embodiments may be combined in a multiplicity of ways and may also be isolated to stand alone as inventions on their own right. For example, the embodiments of depicted in each of FIGS. 1-14 may each stand alone as inventions. Alternatively, the embodiments depicted in FIGS. 1-14 may be combined to function together. By way of example, and with no limitation implied, the embodiments may be combined as follows: (1) an anomaly detector may be combined with a delay element and a measurement unit, which may further be combined with segment sampler, so that an anomalous waveform segment is isolated by virtue of gating, and is segment sampled; (2) a bit clock recovery circuit may be used to clock an anomaly detector that sends a measurement enabling signal to a measurement unit, which is also clocked by the bit recovery circuit, so that an anomalous bit can be measured; (3) the reference architecture of FIG. 8 may be combined with the segment sampler, so that the demultiplexed gated signal may be measured thereby; (4) the reference architecture of FIG. 8 may be combined with an anomaly detector, so that the gate therein isolates an anomalous waveform; (5) the recirculator of FIG. 14 may be combined with a bit clock recovery circuit, so that the gate in the recirculator is driven by a recovered bit clock or a signal derived therefrom; (6) the recirculator of FIG. 14 may be combined with an anomaly detector, so that an anomalous waveform segment may be isolated and recirculated; (7) the recirculator of FIG. 14 may be combined with a measurement unit employing a straddle-measure scheme, so that a threshold crossing may be determined; (8) the recirculator of FIG. 14 may be combined with a measurement unit employing a straddle-measure scheme, which may be further combined with an anomaly detector, so that the isolated and recirculated waveform segment is anomalous and a threshold crossing contained therein is determined; (9) the recirculator of FIG. 14 may be combined with a measurement unit employing a straddle-measure scheme, which may be further combined with a bit clock recovery circuit, so that the gate in the recirculator is driven by the bit clock.

The various embodiments described above are provided by way of illustration only and should not be construed to limit the invention. Those skilled in the art will readily recognize various modifications and changes that may be made to the present invention without following the example embodiments and applications illustrated and described herein, and without departing from the true spirit and scope of the present invention.

The claimed invention is:

1. A method of measuring a segment of a waveform, the method comprising:
receiving a waveform;
gating the waveform, thereby resulting in a gated waveform that is substantially static prior to a first point in time, substantially equal to the waveform between the first point in time and a second point in time, and substantially static following the second point in time; and
providing the gated waveform to a plurality of frequency information extractors, wherein each frequency information extractor yields information regarding at least one of amplitude or phase content of the gated waveform with respect to a frequency that is unique for each frequency information extractor, the gated waveform thereby being represented by the information yielded from the plurality of frequency information extractors.

2. The method of claim 1, wherein the first point in time occurs substantially contemporaneous with an onset of a waveform anomaly, and the second point in time occurs substantially contemporaneous with an end of the waveform anomaly.

3. The method of claim 1, wherein each of the frequencies of the plurality of frequency information extractors is determined based upon the length of time between the first and second points in time.

4. The method of claim 3, wherein each of the frequencies of the plurality of frequency information extractors is a harmonic of a frequency less than the reciprocal of the length of time between the first and second points in time.

5. The method of claim 1, further comprising:
reconstructing the gated waveform from the information yielded from the plurality of frequency information extractors.

6. The method of claim 1, further comprising:
determining a function of time that substantially represents the gated waveform, based upon the information yielded from the plurality of frequency information extractors.

7. The method of claim 6, further comprising:
generating a sequence of data points by using a plurality of time values as arguments of the function of time representing the gated waveform.

8. A method of measuring a waveform anomaly, the method comprising:
receiving a waveform;
conducting the waveform along a first path and a second path, wherein the first path is coupled to a delay element and the second path is coupled to a waveform anomaly detector, wherein the waveform anomaly detector generates a measurement enabling signal upon determining that the waveform contained an anomaly;
conducting the waveform from the delay element to a waveform measuring device; and
activating the waveform measuring device with the measurement enabling signal generated by the waveform anomaly detector, so that the measurement enabling signal arrives at the waveform measuring device substantially contemporaneous with arrival of the anomaly present in the waveform conducted from the delay element.

9. The method of claim 8, wherein the waveform measuring device performs the following steps:
receives the waveform from the delay element;
gates the waveform, thereby resulting in a gated waveform that is substantially static prior to reception of the trigger signal, substantially equal to the waveform between reception of the trigger signal and a second point in time, and substantially static following the second point in time; and
provides the gated waveform to a plurality of frequency information extractors, wherein each frequency information extractor yields information regarding amplitude and phase content of the gated waveform with respect to a frequency that is unique for each frequency information extractor, the gated waveform thereby being represented by the information yielded from the plurality of frequency information extractors.

10. The method of claim 8, wherein the waveform anomaly detector generates the measurement enabling signal if, at a point in time, the waveform has an amplitude that falls on a particular side of a boundary on an amplitude-time coordinate plane.

11. The method of claim 10, wherein the waveform anomaly detector generates the measurement enabling signal if, at a first point in time, the waveform has an amplitude that falls on a first side of a first boundary on an amplitude-time coordinate plane, and at a second point in time, the waveform has an amplitude that falls on second side of a second boundary on the amplitude-time coordinate plane.

12. The method of claim 8, wherein the waveform has at least one bit encoded therein, and wherein the waveform anomaly detector generates the measurement enabling signal upon determining that the bit encoded in the waveform is errant.

13. A method of measuring a waveform with a clock signal encoded therein, the method comprising:
receiving a waveform;
recovering the clock signal encoded in the waveform;
generating a first reference clock signal based upon the recovered clock signal; and
measuring amplitudes of the received waveform at points in time in fixed frequency relation with the first reference clock signal.

14. The method of claim 13, wherein:
the recovered clock signal has a frequency;
the first reference clock signal has a frequency; and
the frequency of the first reference clock signal is a multiple of the frequency of the recovered clock signal.

15. The method of claim 13 further comprising:
generating a second reference clock signal based upon the recovered clock signal; and
measuring a second waveform at points in time in fixed frequency relation with the second sampling clock signal.

16. The method of claim 13, further comprising:
replicating the received waveform;
delaying the replica waveform;
detecting an anomaly in the received waveform on the basis of measuring the received waveform at points in time in fixed frequency relation with the first reference clock signal; and
measuring the delayed replica waveform at points in time in fixed frequency relation with the first reference clock signal, when the anomaly has been detected.

17. A method of identifying distortion introduced into a waveform from gating the waveform, the method comprising:
receiving a waveform carried on a first frequency;
generating a reference signal having a second frequency;
frequency-space multiplexing the received waveform and reference waveform;
gating the multiplexed signal, thereby resulting in a gated multiplexed waveform that is substantially static prior to a first point in time, substantially equal to the multiplexed signal between the first point in time and a second point in time, and substantially static following the second point in time;
demultiplexing the gated multiplexed waveform, thereby yielding a gated waveform carried on the first frequency and a gated reference waveform; and
determining gating distortion introduced into the gated waveform carried on the first frequency based upon the gated reference waveform.

18. The method of claim 17, further comprising correcting the gating distortion introduced to the gated waveform on the first frequency.

19. The method of claim 18, further comprising:
providing the gated waveform carried on the first frequency to a plurality of frequency information extractors, wherein each frequency information extractor yields information regarding amplitude and phase content of the gated waveform carried on the first frequency with respect to a frequency that is unique for each frequency information extractor, the gated waveform carried on the first frequency thereby being represented by the information yielded from the plurality of frequency information extractors.

20. The method of claim 17, wherein the first point in time is determined by an anomaly detector, so that the first point in time substantially coincides with a beginning of an anomaly in the waveform carried on the first frequency.

21. The method of claim 20, further comprising:
determining a function of time that substantially represents the gated waveform carried on the first frequency, based upon the information yielded from the plurality of frequency information extractors.

22. The method of claim 21, further comprising:
generating a sequence of data points by using a plurality of time values as arguments of the function of time representing the gated waveform carried on the first frequency.

23. A method of iteratively providing a segment of a waveform to a measurement system, the method comprising:
receiving an optical waveform;
gating the optical waveform, thereby resulting in a gated optical waveform that is substantially static prior to a first point in time, substantially equal to the optical waveform between the first point in time and a second point in time, and substantially static following the second point in time;
providing the gated optical waveform to a first input of an optical coupler additionally having a second input and an output, the optical coupler combining signals provided at its inputs and yielding the combination at its output, the output of the optical coupler being coupled to an optical splitter, the splitter yielding a first fraction of its input to a first output and a second fraction of its input to a second output, the second output of the splitter being coupled through a fiber loop to the second input of the optical coupler, the first output of the optical splitter being coupled to a measurement system, thereby resulting in the gated waveform being iteratively provided to the measurement system.

24. The method of claim 23, wherein the fiber loop has a fiber length, such that an optical wave propagating from one end of the fiber loop to the other end of the fiber loop consumes a period of time greater than the span of time between the first point in time and the second point in time defining the gating step.

25. The method of claim 23, wherein the fiber loop has an amplifier with a suitable gain interposed therein.

26. The method of claim 23, wherein the optical waveform has a clock signal encoded therein, the method further comprising:
recovering the clock signal from the optical waveform; and
gating the optical waveform with a signal generated from the recovered clock signal.

27. The method of claim 23, wherein the first point in time substantially coincides with a beginning of an anomaly in the optical waveform.

28. A method of automatically determining a point in time at which a repetitive signal crosses a threshold, the method comprising:
sampling the repetitive signal at a first point in time and at a second point in time;
if neither the samples are within a tolerance of the threshold, performing the following steps
waiting for a subsequent repetition of the signal;
stepping in time both samples toward the point in time at which the signal crosses the threshold; and
repeating the preceding two steps until one of the samples is within the tolerance of the threshold.

29. The method of claim 28, wherein the tolerance is selectable.

30. The method of claim 28, wherein the repetitive signal is generated by the following steps:
receiving an optical waveform;
gating the optical waveform, thereby resulting in a gated optical waveform that is substantially static prior to a first point in time, substantially equal to the optical waveform between the first point in time and a second point in time, and substantially static following the second point in time;
providing the gated optical waveform to a first input of an optical coupler additionally having a second input and an output, the optical coupler combining signals provided at its inputs and yielding the combination at its output, the output of the optical coupler being coupled to an optical splitter, the splitter yielding a first fraction of its input to a first output and a second fraction of its input to a second output, the second output of the splitter being coupled through a fiber loop to the second input of the optical coupler, the first output of the optical splitter being coupled to a measurement system operating as described in claim 28, thereby resulting in the gated waveform being repetitively provided to the measurement system operating as described in claim 28.

31. The method of claim 30, wherein the first point in time substantially coincides with a beginning of an anomaly in the optical waveform.

32. The method of claim 30, wherein the optical waveform has a clock signal encoded therein, the method further comprising:
recovering the clock signal from the optical waveform; and
gating the optical waveform with a signal generated from the recovered clock signal.

33. An system for measuring a segment of a waveform, the system comprising:
a gating circuit that gates a waveform, thereby resulting in a gated waveform that is substantially static prior to a first point in time, substantially equal to the waveform between the first point in time and a second point in time, and substantially static following the second point in time; and
a plurality of frequency information extractors coupled to the gating circuit, the plurality of frequency information extractors each receiving the gated waveform as an input, each frequency information extractor yielding information regarding amplitude and phase content of the gated waveform with respect to a frequency that is unique for each frequency information extractor, the gated waveform thereby being represented by the information yielded from the plurality of frequency information extractors.

34. The system of claim 33, wherein each of the frequencies of the plurality of frequency information extractors is determined based upon the length of time between the first and second points in time.

35. The system of claim 33, wherein each of the frequencies of the plurality of frequency information extractors is a harmonic of a frequency less than the reciprocal of the length of time between the first and second points in time.

36. The system of claim 33, further comprising:
a processor coupled to the plurality of frequency information extractors, the processor receiving information from the plurality of frequency information extractors via an input port, the processor being programmed to reconstruct the gated waveform from the information yielded from the plurality of frequency information extractors.

37. The system of claim 33, further comprising:
a processor coupled to the plurality of frequency information extractors, the processor receiving information from the plurality of frequency information extractors via an input port, the processor being programmed to determine a function of time that substantially represents the gated waveform, based upon the information yielded from the plurality of frequency information extractors.

38. The system of claim 37, wherein:
the processor is further programmed to generate a sequence of data points by using a plurality of time values as arguments of the function of time representing the gated waveform.

39. A system for measuring a waveform anomaly, the system comprising:
a splitter that receives a waveform and conducts the waveform along a first path and a second path,
a delay element coupled to the first path;
a waveform anomaly detector coupled to the second path, the waveform anomaly detector generating a measurement enabling signal upon determining that the waveform contained an anomaly; and
a waveform measurement device coupled to the delay element;
wherein the waveform measuring device is activated with the measurement enabling signal generated by the waveform anomaly detector, so that the measurement enabling signal arrives at the waveform measuring device substantially contemporaneous with arrival of the anomaly present in the waveform conducted from the delay element.

40. The system of claim 39, wherein the waveform measuring device comprises:
a gating circuit that gates the waveform from the delay element upon reception of the measurement enabling signal, thereby resulting in a gated waveform that is substantially static prior to reception of the measurement enabling signal, substantially equal to the waveform from the delay element between reception of the measurement enabling signal and a second point in time, and substantially static following the second point in time; and
a plurality of frequency information extractors coupled to the gating circuit, the plurality of frequency information extractors each receiving the gated waveform as an input, each frequency information extractor yielding information regarding amplitude and phase content of the gated waveform with respect to a frequency that is unique for each frequency information extractor, the gated waveform thereby being represented by the information yielded from the plurality of frequency information extractors.

41. The system of claim 39, wherein the waveform anomaly detector is configured and arranged to generate the measurement enabling signal if, at a point in time, the waveform has a level that falls outside of a boundary defined by a relationship to a point on a level-time coordinate plane.

42. The system of claim 41, wherein the waveform anomaly detector is configured and arranged to generate the measurement enabling signal if, at a point in time, the waveform has a level that falls outside of a boundary defined by a relationship to a plurality of points on a level-time coordinate plane.

43. The system of claim 39, wherein the waveform has at least one bit encoded therein, and wherein the waveform anomaly detector is configured and arranged to generate the measurement enabling signal upon determining that the bit encoded in the waveform is errant.

44. A system for measuring a waveform with a clock signal encoded therein, the system comprising:
a recovery circuit that recovers the clock signal encoded in the waveform;
a clock generation circuit coupled to the recovery circuit, the clock generation circuit generating a first reference clock signal based upon the recovered clock signal; and
a waveform measurement device that measures amplitudes of the received waveform at points in time in fixed frequency relation with the first reference clock signal.

45. The system of claim 44, wherein the recovered clock signal has a frequency and the first reference clock signal has a frequency, and wherein the clock generation circuit comprises a multiplication circuit configured and arranged so that the frequency of the first reference clock signal is a multiple of the frequency of the recovered clock signal.

46. The system of claim 44 further comprising:
a second measurement device that measures amplitudes of a second received waveform at points in time in fixed frequency relation with the first reference clock signal.

47. The system of claim 44, further comprising:
a splitter that receives the waveform and conducts the waveform along a first path and a second path,
a delay element coupled to the first path; and
a waveform anomaly detector coupled to the second path, the waveform anomaly detector generating a measurement enabling signal upon determining that the waveform contained an anomaly, the waveform anomaly detector detecting an anomaly in the received waveform on the basis of measuring the received waveform at points in time in fixed frequency relation with the first reference clock signal;
wherein the waveform measurement device is coupled to the delay element;
wherein the waveform measurement device is activated with the measurement enabling signal generated by the waveform anomaly detector, so that the measurement enabling signal arrives at the waveform measurement device substantially contemporaneous with arrival of the anomaly present in the waveform conducted from the delay element.

48. A system for identifying distortion introduced into a waveform from gating the waveform, the system comprising:
a laser generating a reference signal having a second frequency;
a frequency-space multiplexer that multiplexes a waveform carried on a first frequency and the reference signal;
a gating circuit coupled to the multiplexer, the gating circuit gating the multiplexed signal, thereby resulting in a gated multiplexed waveform that is substantially static prior to a first point in time, substantially equal to the multiplexed signal between the first point in time and a second point in time, and substantially static following the second point in time;
a demultiplexing circuit coupled to the gating circuit, the demultiplexing circuit demultiplexing the gated multiplexed waveform, thereby yielding a gated waveform carried on the first frequency and a gated reference signal;
a measurement unit coupled to the demultiplexing circuit, the measurement unit acquiring and digitizing information regarding the gated reference signal and gated waveform carried on the first frequency; and
a processor coupled to the measurement unit, the processor being programmed to determine gating distortion introduced into the gated waveform carried on the first frequency, based upon the gated reference signal.

49. The system of claim 48, wherein the processor is further programmed to correct the gating distortion introduced to the gated waveform carried on the first frequency.

50. The system of claim 49, further comprising:
a plurality of frequency information extractors coupled to the demultiplexing circuit, so that the plurality of frequency information extractors receives the gated waveform carried on the first frequency, wherein each frequency information extractor yields information regarding amplitude and phase content of the gated waveform carried on the first frequency with respect to a frequency that is unique for each frequency information extractor, the gated waveform carried on the first frequency thereby being represented by the information yielded from the plurality of frequency information extractors.

51. The system of claim 48, wherein the first point in time is determined by an anomaly detector, so that the first point in time substantially coincides with a beginning of an anomaly in the waveform carried on the first frequency.

52. The system of claim 51, wherein the processor is further programmed to determine a function of time that substantially represents the gated waveform carried on the first frequency, based upon the information yielded from the plurality of frequency information extractors.

53. The method of claim 52, wherein the processor is further programmed to generate a sequence of data points by using a plurality of time values as arguments of the function of time representing the gated waveform carried on the first frequency.

54. A system for iteratively providing a segment of a waveform to a measurement system, the method comprising:
a gating circuit that gates an optical waveform, thereby resulting in a gated optical waveform that is substantially static prior to a first point in time, substantially equal to the optical waveform between the first point in time and a second point in time, and substantially static following the second point in time;
an optical coupler having a first and second input and an output, the first input being coupled to the gating circuit, thereby receiving the gated optical waveform, the optical coupler combining signals provided at its first and second inputs and yielding the combination at its output;
an optical splitter being coupled to the output of the optical coupler, the optical splitter yielding a first fraction of its input to a first output and a second fraction of its input to a second output, the second output of the splitter being coupled through a fiber loop to the second input of the optical coupler; and
a measurement system coupled to the first output of the optical splitter, thereby iteratively receiving the gated waveform.

55. The system of claim 54, wherein the fiber loop has a fiber length, such that an optical wave propagating from one end of the fiber loop to the other end of the fiber loop consumes a period of time greater than the span of time between the first point in time and the second point in time defining the gating step.

56. The system of claim 54, wherein the fiber loop has an amplifier with a suitable gain interposed therein.

57. The system of claim 54, wherein the optical waveform has a clock signal encoded therein, the system further comprising:
a recovery circuit that recovers the clock signal encoded in the optical waveform;
a clock generation circuit coupled to the recovery circuit, the clock generation circuit generating a first reference clock signal based upon the recovered clock signal, wherein the gating circuit is clocked with the first reference clock signal.

58. The system of claim 54, wherein the first point in time substantially coincides with a beginning of an anomaly in the optical waveform.

59. A waveform measurement device that determines a point in time at which a repetitive signal crosses a threshold, the waveform measurement device comprising:
a sampling unit that receives and samples the repetitive signal; and
a processor coupled to the sampling unit, the processor controlling timing of the sampling conducted by the sampling unit, the processor programmed to perform the following steps
sample the repetitive signal at a first point in time and at a second point in time;
if neither the samples are within a tolerance of the threshold, perform the following steps
wait for a subsequent repetition of the signal;
step in time both samples toward the point in time at which the signal crosses the threshold; and
repeat the preceding two steps until one of the samples is within the tolerance of the threshold.

60. The waveform measurement device of claim 59, wherein the tolerance is selectable.

61. The waveform measurement device of claim 59, wherein the repetitive signal is generated by a system comprising:
a gating circuit that gates an optical waveform, thereby resulting in a gated optical waveform that is substantially static prior to a first point in time, substantially equal to the optical waveform between the first point in time and a second point in time, and substantially static following the second point in time;
an optical coupler having a first and second input and an output, the first input being coupled to the gating circuit, thereby receiving the gated optical waveform, the optical coupler combining signals provided at its first and second inputs and yielding the combination at its output;
an optical splitter being coupled to the output of the optical coupler, the optical splitter yielding a first fraction of its input to a first output and a second fraction of its input to a second output, the second output of the splitter being coupled through a fiber loop to the second input of the optical coupler; and
the sampling unit of the waveform measurement device coupled to the first output of the optical splitter, thereby repetitively receiving the gated waveform.

62. The waveform measurement device of claim 59, wherein the optical waveform has a clock signal encoded therein, the waveform measurement device further comprising:
a recovery circuit that recovers the clock signal encoded in the optical waveform;
a clock generation circuit coupled to the recovery circuit, the clock generation circuit generating a first reference clock signal based upon the recovered clock signal, wherein the sampling unit is commanded to conduct samples based upon the first reference clock signal.
